(19) United States
(12) Patent Application Publication
(10) Pub. No.: US 2025/0130124 A1
(43) Pub. Date: Apr. 24, 2025

(54) METHOD FOR CONSTRUCTING A FORCE SENSOR GROUP, AND FORCE SENSOR GROUP FOR A MOTOR VEHICLE

(71) Applicant: HELLA GmbH & Co. KGaA, Lippstadt (DE)

(72) Inventors: Steffen HOPPE, Lippstadt (DE); Andreas KUPEZKI, Lippstadt (DE); Stefan PETERS, Lippstadt (DE)

(73) Assignee: HELLA GmbH & Co. KGaA, Lippstadt (DE)

(21) Appl. No.: 18/920,764

(22) Filed: Oct. 18, 2024

(30) Foreign Application Priority Data
Oct. 18, 2023 (DE) 10 2023 128 543.2

(51) Int. Cl. G01L 1/22

(52) U.S. Cl. CPC G01L 1/2293

(57) ABSTRACT

A method for constructing a force sensor group is provided. An expansion body is provided that has integrated force sensor elements. A printed circuit board is provided having electronic components that are configured to receive measurement signals from the force sensor elements. The printed circuit board is electrically connected to the force sensor elements of the expansion body. The electrical connections are protected by applying a potting compound to the electrical connections. Media-tight overmolding of the printed circuit board is performed and at least sections of the expansion body to seal the electronic components and the force sensor elements or to seal and to mechanically protect the electronic components and the force sensor elements.

This nonprovisional application claims priority under 35 U.S.C. § 119(a) to German Patent Application No. 10 2023 128 543.2, which was filed in Germany on Oct. 18, 2023, and which is herein incorporated by reference.

### BACKGROUND OF THE INVENTION

### Field of the Invention

The invention relates generally to the field of force sensors for motor vehicles. Specifically, the invention relates to a method for constructing a force sensor group, to a force sensor group, and to a motor vehicle having such a force sensor group.

### Description of the Background Art

Force sensors for motor vehicles, such as for use on the brake piston of motor vehicles, for example, are generally exposed to a harsh environment. High temperatures, brake dust, and water spray can arise in such an environment. Force sensors must also be able to withstand stone impact as well as most chemicals encountered in a motor vehicle. In addition, any high-pressure cleaners and/or stone impacts and other mechanical stresses must not influence the functioning of the force sensors.

A sealing method for encapsulating the force sensor with thermoplastics is known from CN 213180430. In order to close the gaps produced thereby and to attach the component parts to one another, it is proposed here to provide a connection by laser welding.

Known methods for sealing force sensors are costly, however, and require high precision in order to be able to ensure a certain seal. Moreover, most known seals merely provide protection primarily from mechanical stress.

### SUMMARY OF THE INVENTION

It is therefore an object of the present invention to at least partially overcome the above-described disadvantages in force sensor groups for motor vehicles. In particular, it is an object of the present invention to provide a simple and efficient method for constructing a force sensor group for a motor vehicle, wherein the force sensor group constructed thereby is advantageously sealed against chemicals or media and preferably is optimally protected from mechanical stress.

The above object is attained by a method, by a force sensor group for a motor vehicle, and by a motor vehicle. Additional features and details of the invention are evident from the description and the drawings. Of course, features and details that are described in connection with the method according to the invention also apply in connection with the force sensor group according to the invention and/or the motor vehicle and vice versa in each case, so mutual reference is or can always be made with regard to the disclosure of the individual aspects of the invention.

An improved method for constructing a force sensor group for a motor vehicle can be provided advantageously through examples of the invention. A robust and durable force sensor group for a motor vehicle can be constructed in an efficient and simple manner with such a method.

A first aspect of the present disclosure relates to a method for constructing a force sensor group, in particular for a motor vehicle. The method has the following steps: providing an expansion body that has integrated force sensor elements; providing a printed circuit board having electronic components that are configured to receive measurement signals from the force sensor elements; electrically connecting the printed circuit board to the force sensor elements of the expansion body; protecting the electrical connections by applying a potting compound to the electrical connections; and media-tight overmolding of the printed circuit board and at least sections of the expansion body to seal the electronic components and the force sensor elements or to seal and to mechanically protect the electronic components and the force sensor elements.

In other words, a first assembly formed of a populated printed circuit board with installed and contacted connector can be provided or created. After that or at the same time, a second assembly formed of an expansion body with integrated force sensor elements can be provided. The force sensor elements can be strain gauges. The strain gauges can be installed on the expansion body. In another method step, the two assemblies can be electrically connected to one another, in particular the force sensor elements to the printed circuit board. In addition, the two assemblies can be mechanically connected to one another, for example by latching or adhesive bonding. The electrical connection between the printed circuit board and the expansion body, or the force sensor elements of the expansion body, can be created by bonding. The electrical connection can therefore be referred to as a bond connection.

The electrical connection can subsequently be protected by the application of a potting compound. Liquid encapsulation, also referred to as glob top, can be used for this purpose. The potting compound can cure and thus protect the electrical connection from external influences.

In a final method step, the printed circuit board and at least sections thereof can be sealed by means of media-tight overmolding. In other words the system, formed of both assemblies, can be encapsulated.

The expansion body can be designed in the manner of a donut. Another example would be a circular expansion body. Other forms, as for example thrust members or others, expressly should not be precluded. The printed circuit board can be designed as a flat ring or in another shape matched to the expansion body. The expansion body can be a piece of material, such as, e.g., metal or plastic or another material, that can deform under the influence of forces. The deformation can be sensed and/or measured owing to the force sensor elements.

Various materials can be used for the media-tight overmolding. A potting solution or a varnish can be used. Thermosetting materials can be used as a potting solution. For example, silicone, epoxide, and/or polyurethane or others can be used as thermosetting material. Silicone is highly elastic and soft and can withstand temperatures up to 200° C. Epoxide offers high hardness and has high temperature and chemical resistance. Polyurethane is also very well suited as a thermoset, but can withstand temperatures of only up to 120° C.

The thermoset materials can be optimized by means of fillers to the effect that the coefficients of thermal expansion of the material itself approximate those of the printed circuit board or of the electrical components, but also the expansion body.

The mechanical robustness of the entire force sensor group can be increased by such a method. Furthermore, both a mechanical protection and a sealing against chemicals can be provided for the entire force sensor group by the media-tight overmolding. The media-tight sealing can advantageously ensure a protection against environmental chemical influences. The chemicals can be fuel or cleaning fluid, for example. The mechanical protection can ensure a protection against mechanical stress, wherein mechanical stress can include vibrations and/or oscillations.

The step of media-tight overmolding can have the following intermediate steps: positioning an open housing on the expansion body in a sealing manner, and introducing thermoset, in particular thermoset that is still liquid, into the open housing in order to overmold the printed circuit board and at least sections of the expansion body in a media-tight manner.

The open housing can be a frame that can be placed on the contour of the expansion body in a sealing manner. The open housing is preferably placed on the expansion body in an interlocking, sealing manner—in particular so as to seal against potting solutions. The open housing should be positioned on the expansion body in a sealing manner, in particular in such a way that no thermoset can penetrate between the two elements. When it is positioned on the expansion body in a sealing manner, the open housing preferably forms a cavity into which the thermoset can be introduced. The inner contour of the open housing can therefore correspond to the contour of the expansion body. The open housing can be designed as an open cylinder, for example. In addition, the open housing can have a latching unit that is configured to latch and/or to mechanically attach the open housing to the expansion body. It should be noted that, after the introducing of the thermoset, the thermoset preferably will cure.

The cured thermoset has outstanding chemical resistance to most environmental influences. Consequently, the printed circuit board and at least sections of the expansion body can be protected in a simple and efficient manner from chemicals and mechanical stress as a result.

The open housing can be pressed against the expansion body with a predetermined pressure while the thermoset is introduced into the open housing. As a result, it can be ensured that only the desired volume and/or the desired area on the printed circuit board and on the expansion body is sealed by the thermoset when the thermoset is introduced, in particular thermoset that is still liquid. If at all possible, there should be no gap between the open housing and the expansion body, for which reason it can prove advantageous to press the open housing against the expansion body with a predetermined pressure. In this way, the thermoset can be applied precisely and cleanly. The predetermined pressure can be between 40 and 60 bar, for instance.

After the introducing of thermoset into the open housing and after the curing of the thermoset, the open housing can be removed from the force sensor group. For this purpose, the open housing can be expandable, for example. It is also possible that pressing the open housing against the expansion body with the predetermined pressure is stopped after the thermoset is introduced.

The open housing can be broken during removal of the open housing. This can prove advantageous, for example when the open housing is designed as one piece and is flush on the expansion body, for instance owing to the pressing.

The open housing can have a thermoplastic. This can prove advantageous, in particular because a sealing connection between the expansion body and the open housing can be achieved by this means. A sealing connection between these two elements can permit a precise and efficient introduction of thermoset. Thermoplastic material can offer good adhesion of the open housing to the expansion body.

The thermoset can be injected during the media-tight overmolding of the printed circuit board and at least sections of the expansion body. By this means, the electronic components and the force sensor elements can be efficiently sealed and protected from mechanical stress.

The open housing can be attached to the expansion body. In addition, thermoset is poured into the open housing up to a specified level. For this purpose, provision can be made to irreversibly attach the open housing to the expansion body, for example by adhesive bonding. The open housing can therefore be configured to not be removed after the introduction of thermoset. The force sensor group can therefore constitute an open container after such a method. In contrast to an example in which the open housing is configured so as to be removed, this example offers the advantage that no pressure need be applied to the open housing during the introduction of thermoset. However, the force sensor group constructed in this manner does occupy considerably more space.

The thermoset can be poured into the open housing under the application of a vacuum. The method can be further improved in this way.

The step of media-tight overmolding can have the following intermediate steps: positioning, in particular attaching, an open housing on the expansion body in a sealing manner, and coating the printed circuit board and at least sections of the expansion body with varnish.

In other words, it is possible to protect the completed device, i.e., the printed circuit board and at least sections of the expansion body, by means of a varnish coating. In this case, the assembly having printed circuit board and expansion body with an open housing, in particular with a molded-on housing, can be flow-coated with varnish. Subsequently, the excess varnish can be poured out. For this purpose, the force sensor group can be flipped by 180° for a predefined period. The varnish adhering to the printed circuit board or to the electronic components of the printed circuit board and, in particular, to a connector group of the printed circuit board then protects the sensitive electronics from environmental chemical influences.

As a result, a chemical protection for the electrical components and the force sensor elements can be ensured in an efficient manner. Lower manufacturing costs can be achieved by such a method.

A second aspect of the present invention relates to a force sensor group for a motor vehicle. The force sensor group has an expansion body with integrated force sensor elements, and a printed circuit board having electronic components that are configured to receive measurement signals from the force sensor elements and to establish at least one electrical connection between the printed circuit board and the expansion body. The force sensor group additionally has a media-tight sealing of the printed circuit board and at least sections of the expansion body. The media-tight sealing is designed, in particular, to seal the electronic components and the force sensor elements or to seal and to mechanically protect the electronic components and the force sensor elements.

All of the advantages cited with respect to the method according to the first aspect of the invention also apply in like manner to the force sensor group for a vehicle according to the second aspect of the invention.

According to an example of the force sensor group, the media-tight sealing has thermoset.

The force sensor group further can have an open housing that is attached in a sealing manner to the expansion body and in particular to the printed circuit board.

The force sensor group can be constructed according to the method according to the first aspect of the present invention.

A third aspect of the present invention relates to a motor vehicle. The motor vehicle has a force sensor group according to the second aspect of the present invention.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a perspective view of a printed circuit board with an expansion body,

FIG. 2 shows a force sensor group according to an example,

FIG. 3 shows a force sensor group according to an example,

FIG. 4 shows a force sensor group according to an example, and

FIG. 5 shows a flowchart of a method according to an example.

### DETAILED DESCRIPTION

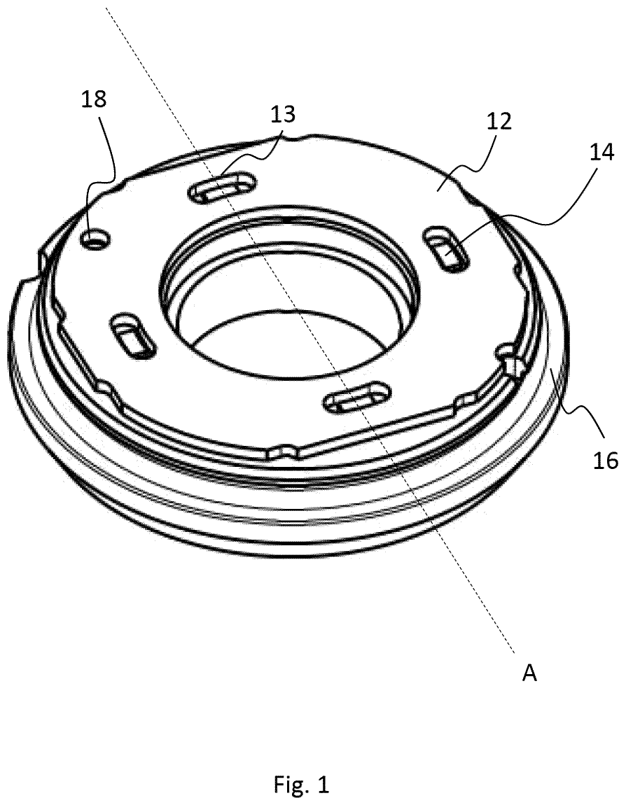

FIG. 1 shows a perspective view of a printed circuit board with an expansion body. The expansion body 16 is designed in the manner of a donut or tire, and has force sensor elements 14, which can be designed as strain gauges. The expansion body 16 can also be designed as a ring, wherein the printed circuit board 12 is applied or attached to a first face of the ring. The force sensor elements preferably are applied to the first face of the ring or of the expansion body. The force sensor elements 14 can be uniformly distributed on the first face of the expansion body 16. The force sensor elements 14 can be distributed rotationally symmetrically.

The printed circuit board 12 can likewise be designed in a ring shape. The printed circuit board 12 can have a bore 18, which serves to position the printed circuit board 12. The printed circuit board 12 preferably is connected mechanically and chemically (adhesive bonding) to the expansion body. Alternatively, the printed circuit board 12 can be attached to the expansion body by means of a mechanical connection, such as by latching. The printed circuit board 12 is also electrically connected to the force sensor elements 14 of the expansion body. The printed circuit board 12 of the force sensor group 100 can have apertures 13, or holes, which are arranged above the respective force sensor elements 14 in the installed state of the printed circuit board 12 on the expansion body 16. The distribution of the apertures 13 of the printed circuit board 12 corresponds to the distribution of the force sensor elements 14 of the expansion body 16 and can also be located on the edge of the printed circuit board so that they do not have to form holes.

The electrical components of the printed circuit board 12 are configured to receive signals from the force sensor elements 14. It should be noted that a support surface can be arranged on the expansion body between the expansion body 16 and the printed circuit board 12, at least in sections or areas, in order to permit stable seating of the printed circuit board.

The force sensor elements 14 from FIG. 1 are covered with a protective material or potting compound in the cavities formed by the openings or the aperture 13 of the printed circuit board 12, moreover.

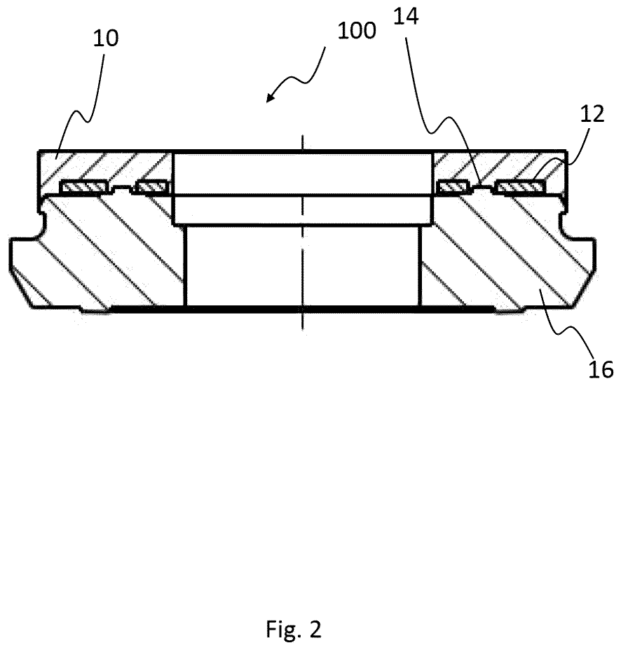

FIG. 2 shows a force sensor group 100 according to an example. Unless described otherwise, the printed circuit board 12 and the expansion body 16 in FIG. 2 have the same elements and/or components as the printed circuit board 12 and the expansion body 16 from FIG. 1. FIG. 2 shows a cross section through a force sensor group 100, wherein the cross section is along the axis A, see FIG. 1.

The force sensor group 100 has a media-tight sealing of the printed circuit board 12 and at least sections of the expansion body. The media-tight sealing of the force sensor group 100 in FIG. 2 formed of injection-molded thermoset 10. For this purpose, an open housing 19 was positioned on the expansion body 16 in a sealing manner. The expansion body 16 can have a circumferential latching unit 15, over which the open housing 19 can be positioned on the expansion body 16 in a sealing manner. The open housing 19 and the printed circuit board 12 and the expansion body 16 together form a cavity, which can be filled with thermoset 10. The thermoset can be introduced with pressure into the open housing 19 or into the cavity formed thereby.

The thermoset 10 can subsequently cure. For this purpose, provision can be made to wait a curing period. Finally, the open housing 19 is removed after curing of the thermoset 10. The thermoset 10 thus covers and protects any electronic components of the printed circuit board 12 as well as the force sensor elements 14 of the expansion body 16 from mechanical stress and environmental chemical influences. The thermoset 10 preferably is not in direct contact with the force sensor elements 14, since these may be covered by a potting compound, or a glob top.

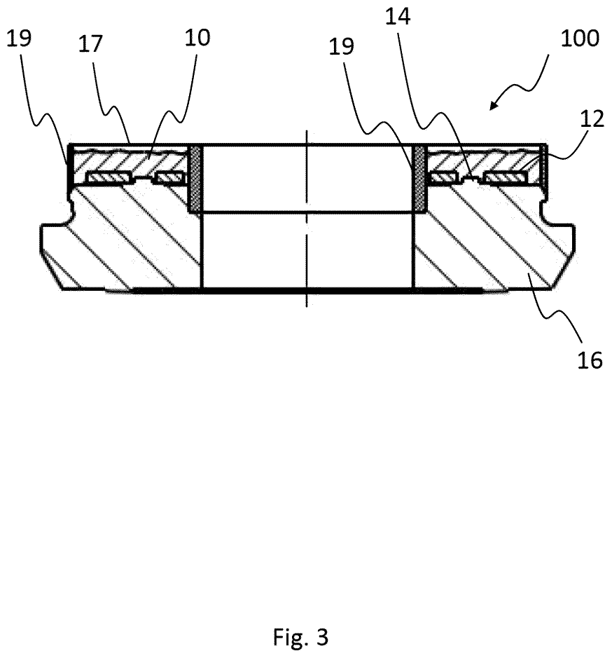

FIG. 3 shows a force sensor group 100 according to another example. Unless described otherwise, the force sensor group 100 from FIG. 3 has the same elements and/or components as the force sensor group 100 from FIG. 2.

In contrast to the force sensor group 100 from FIG. 2, the force sensor group 100 from FIG. 3 has the open housing 19. The open housing 19 is attached to the expansion body 16, preferably irreversibly attached. The open housing 19 therefore is in circumferential interlocking contact with the expansion body 16. The open housing 19, which can also be referred to as a frame, forms a cavity, which can be filled with thermoset 10. After the attachment of the housing 19 to the expansion body 16, the thermoset can be poured—in particular without pressure—into the cavity formed by the housing up to a specified level 17.

The thermoset 10 thus forms a seal of the electronic components and the force sensor elements 14 or a seal and a mechanical protection of the electronic components and the force sensor elements 14.

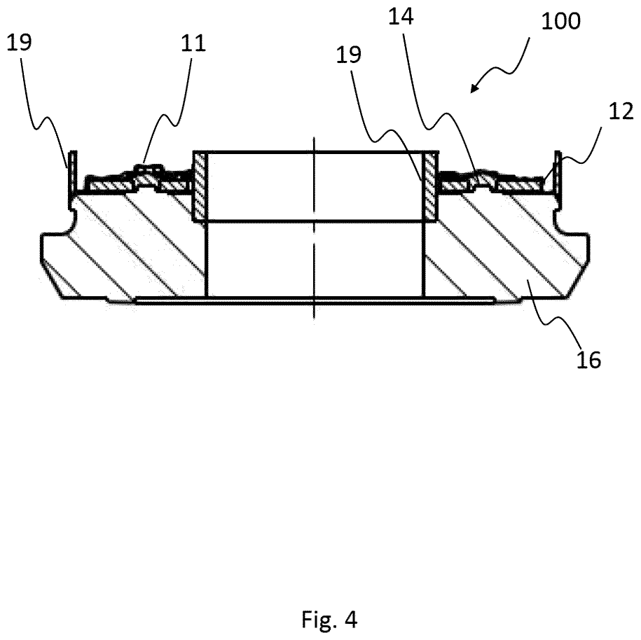

FIG. 4 shows a force sensor group 100 according to an example. Unless described otherwise, the force sensor group 100 from FIG. 4 has the same elements and/or components as the force sensor group 100 from FIGS. 2 and 3. Similar to the force sensor group 100 from FIG. 3, the force sensor group 100 in FIG. 4 likewise has an open housing 19, which forms a frame. The printed circuit board 12 and at least sections of the expansion body 16 can be protected from environmental chemical influences by means of a varnish coating 11. The force sensor group 100 with molded-on housing 19 can be flow-coated with varnish and afterwards poured out again (upside down). The varnish adhering to the printed circuit board 12, the expansion body 16, and the open housing 19 then protects the sensitive electronics of the force sensor group 100 from environmental chemical influences. The varnish 11 can form a continuous, thin layer, which extends, in particular, from the external interior wall of the open housing 19 to the internal interior wall of the open housing 19.

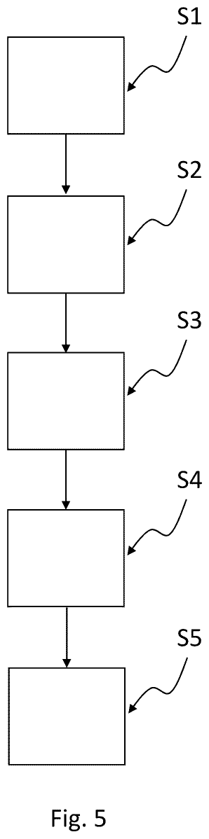

FIG. 5 shows a flowchart of a method for constructing a force sensor group 100, in particular a force sensor group 100 for a motor vehicle according to an example. The method has the following steps: In a first method step S1, an expansion body 16 that has integrated force sensor elements 14 is provided. The force sensor elements 14 are configured to sense and/or to measure an expansion of the expansion body 16. In a second method step S2, which preferably takes place after the first method step S1, a printed circuit board 12 having electronic components is provided. The electronic components are configured to receive measurement signals from the force sensor elements 14. In a third method step S3, which follows the second method step, the printed circuit board 12 is electrically connected to the force sensor elements 14 of the expansion body 16, in particular by means of a bond connection. In a fourth method step S4, the electrical connections are protected by the application of a potting compound, such as a glob top, which is poured onto the electrical connections. In other words, the bond connections are protected by glob top in the fourth method step. In a last and fifth method step S5, the printed circuit board 12 and at least sections of the expansion body 16 are overmolded in a media-tight manner to seal the electronic components and the force sensor elements 14 or to seal and to mechanically protect the electronic components and the force sensor elements 14. As a result, the entire system can be encapsulated, by which means the force sensor group 100 can advantageously be protected against mechanical stress or can advantageously be protected against environmental chemical influences and mechanical stress.

The fifth method step S5 can have the following intermediate steps: media-tight encapsulation of the printed circuit board 12 and at least sections of the expansion body 16 to seal the electronic components and the force sensor elements 14 or to seal and to mechanically protect the electronic components and the force sensor elements 14; and/or media-tight varnish coating of the printed circuit board 12 and at least sections of the expansion body 16 to seal the electronic components and the force sensor elements 14 or to seal and to mechanically protect the electronic components and the force sensor elements 14.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for constructing a force sensor group, the method comprising:
providing an expansion body that has at least one integrated force sensor element;
providing a printed circuit board having at least one electronic component that is configured to receive at least one measurement signal from the force sensor elements;
electrically connecting the printed circuit board to the force sensor element of the expansion body;
protecting an electrical connection by applying a potting compound to the electrical connections; and
media-tight overmolding of the printed circuit board and at least one section of the expansion body to seal the electronic component and the force sensor element or to seal and to mechanically protect the electronic component and the force sensor element.

2. The method according to claim 1, wherein the step of media-tight overmolding comprises:
Positioning an open housing on the expansion body in a sealing manner; and
introducing thermoset into the open housing in order to overmold the printed circuit board and at least sections of the expansion body in a media-tight manner.

3. The method according to claim 2, wherein the open housing is pressed against the expansion body with a predetermined pressure while the thermoset is introduced into the open housing.

4. The method according to claim 2, wherein the open housing is removed from the force sensor group after introduction of thermoset into the open housing.

5. The method according to claim 1, wherein the open housing has thermoplastic.

6. The method according to claim 1, wherein the thermoset is injected during the media-tight overmolding of the printed circuit board and at least sections of the expansion body.

7. The method according to claim 1, wherein the open housing is attached to the expansion body, and the thermoset is poured into the open housing up to a specified level.

8. The method according to claim 7, wherein thermoset is poured into the open housing under the application of a vacuum.

9. The method according to claim 1, wherein the step of media-tight overmolding comprises:
positioning or attaching an open housing on the expansion body in a sealing manner; and
coating the printed circuit board and at least sections of the expansion body with varnish.

10. A force sensor group for a motor vehicle, the force sensor group comprising:
an expansion body with at least one integrated force sensor element;
a printed circuit board having at least one electronic component that is configured to receive at least one measurement signal from the force sensor element and to establish at least one electrical connection between the printed circuit board and the expansion body; and
a media-tight seal of the printed circuit board and at least sections of the expansion body.

11. The force sensor group according to claim 10, wherein the media-tight seal has thermoset.

12. The force sensor group according to claim 10, further comprising an open housing that is attached in a sealing manner to the expansion body and to the printed circuit board.

13. A force sensor group constructed in accordance with the method according to claim 1.

14. A motor vehicle comprising a force sensor group according to claim 10.
